(19) United States
(12) Patent Application Publication
(10) Pub. No.: US 2004/0082118 A1
(43) Pub. Date: Apr. 29, 2004

(54) Semiconductor device with lightly doped drain and method of manufacturing the same

(76) Inventors: Shih-Chang Chang, Hsinchu (TW); Yaw-Ming Tsai, Taichung (TW)

Correspondence Address: Michael D. Bednarek, Shaw Pittman LLP, 1650 Tysons Boulevard, McLean, VA, 22102, US

(21) Appl. No.: 10/690,703

(22) Filed: Oct. 23, 2003

(30) Foreign Application Priority Data
Oct. 25, 2002 (TW) 091124959

(51) Int. Cl. H01L 21/84; H01L 21/00

(52) U.S. Cl. 438/154

(57) ABSTRACT

A semiconductor device with a lightly doped drain and a method of manufacturing the same are provide. The method includes the step of providing a semiconductor substrate having a first area and a second area. A gate dielectric layer and a conductive layer are subsequently formed on the semiconductor substrate. The conductive layer is then selectively removed so that a first gate electrode is formed on the gate dielectric layer corresponding to the first area, and a portion of remains of the conductive layer substantially overlies the second area. A first impurity of first conduction type is then doped in the first area. A spacer is formed on a sidewall of the first gate electrode. A second impurity of first conduction type is doped in the first area to form a thin film transistor of first conduction type. A patterned mask layer defining a second gate electrode of the conductive layer corresponding to the second area is formed over the semiconductor substrate. A portion of the conductive layer is removed to form the second gate electrode on the gate dielectric layer corresponding to the second area. Then, an impurity of second conduction type is doped in the second area to form a thin film transistor of second conduction type.

### CROSS REFERENCE TO RELATED APPLICATIONS

This application claims priority to Taiwan Patent Application No. 091124959 entitled “Semiconductor Device with Lightly Doped Drain and Manufacturing Method thereof”, filed on Oct. 25, 2002.

### FIELD OF INVENTION

The present invention relates to a semiconductor device and its manufacture method, and more particularly, to a thin film transistor with lightly doped drain (LDD) and a method of manufacturing the same.

### BACKGROUND OF THE INVENTION

Semiconductor devices generally have lots of circuits and devices to control their functions, and the thin film transistor (TFT) is one of the most commonly implemented devices. For example, in the liquid crystal display (LCD) device, the thin film transistors are often used as pixel switching elements, or switches in a driver circuit.

However, as the channel length of thin film transistors keeps on shrinking, the short channel effect seriously affects the operation of the thin film transistors. For example, the high electric field near the drain of TFT usually induces high leakage currents. Therefore, lightly doped drain (LDD) structure, offset gate structure, or multi-gate structure are conventionally implemented by designers to suppress the high electric field. The lightly doped drain technique, among others, is most commonly adopted to reduce the leakage current when the transistor is at ON state.

The conventional method of forming a lightly doped structure usually needs extra masks, which increases the production cost and complicates the manufacturing process. For example, in the conventional method, the photolithography process usually defines the LDD length. When misalignment occurs in the photolithography process, a variation in the LDD length is induced. Therefore, it is important to reduce the number of masks and improve the alignment accuracy of the photolithography process in manufacturing TFT-LCD devices.

As disclosed in U.S. Pat. No. 6,306,693, the conventional method performs a first n-type-doping step after the gate electrode of the n-typed transistor is etched. Then, the patterned mask layer used for forming the gate electrode is left and used to perform side etching of a portion of the gate electrode, and then is removed. The side-etched gate electrode is then used as a mask to perform a second n-type-doping step to define the lightly doped region, and therefore the number of masks is reduced. However, the result of side etching (or undercut etching) process is difficult to control, which induces a variation in the amount of side etching of the gate electrode. As a result, the subsequent doping step creates a variation in the LDD length. Therefore, it is desired to provide a method of simplified step for forming a semiconductor device with a uniform LDD length.

### SUMMARY OF THE INVENTION

It is one aspect of the present invention to provide a semiconductor device with lightly doped drain (LDD). The semiconductor device has a spacer serving as a hard mask to prevent variations in the LDD length during the formation of LDDs.

It is another aspect of the present invention to provide a method of manufacturing a semiconductor device, which eliminates variations in the LDD length induced by misalignment of the photolithography process.

It is a further aspect of the present invention to provide a method of forming a thin film transistor, which implements a spacer as a selfaligned hard mask to prevent deviations of a patterned photoresist layer.

It is a further another aspect of the present invention to provide a method of forming driver/control circuits of a liquid crystal display (LCD), which uses simplified processing steps to form devices with lightly doped drains in the process of forming a spacer and gate electrodes of different conduction type transistors.

In one exemplary embodiment, the method includes the step of providing a semiconductor substrate having a first area and a second area for respectively forming a first conduction type thin film transistor and a second conduction type thin film transistor. A gate dielectric layer is formed on the semiconductor substrate, and a conductive layer is formed on the gate dielectric layer. A portion of the conductive layer is selectively removed to form a first gate electrode on the gate dielectric layer, which corresponds to the first area. A portion of remains of the conductive layer substantially overlies the second area. A first impurity of a first conduction type is doped in the first area. A spacer is formed on a sidewall of the first gate electrode. A second impurity of first conduction type is doped in the first area to form the first conduction type transistor. A patterned mask layer is formed over the semiconductor substrate. The patterned mask layer defines a second gate electrode of the conductive layer, which corresponds to the second area. A portion of the conductive layer, which corresponds to the second area, is removed to form the second gate electrode on the gate dielectric layer by using the patterned mask layer as a mask. An impurity of a second conduction type is doped in the second area to form the second conduction type transistor.

In another exemplary embodiment, a semiconductor device with a lightly doped region includes a semiconductor substrate having a first area and a second area, a first type transistor formed in the first area, and a second type transistor formed in the second area.

Each of the first type and second type transistors includes source/drain regions, a gate dielectric layer, and a gate electrode. The source/drain regions are formed in the semiconductor substrate and separated by a channel. The gate dielectric layer is formed on the semiconductor substrate covering the channel. The gate electrode is formed on the gate dielectric layer corresponding to the channel. The first type transistor further includes a spacer and a lightly doped region. The spacer is formed on a sidewall of the gate electrode and on the gate dielectric layer corresponding to the first area. The lightly doped region is formed in a portion of the source/drain region corresponding to the spacer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a cross-sectional view of forming a conductive layer in one exemplary embodiment of the present invention;

FIG. 2 illustrates a cross-sectional view of forming a patterned photoresist layer defining a first gate electrode in one exemplary embodiment of the present invention;

FIG. 3 illustrates a cross-sectional view of forming a first gate electrode in one exemplary embodiment of the present invention;

FIG. 4 illustrates a cross-sectional view of implanting first n-type ions in one exemplary embodiment of the present invention;

FIG. 5 illustrates a cross-sectional view of forming a conformal dielectric layer in one exemplary embodiment of the present invention;

FIG. 6 illustrates a cross-sectional view of implanting second n-type ions in one exemplary embodiment of the present invention;

FIG. 7 illustrates a cross-sectional view of a patterned photoresist layer defining a second gate electrode in one exemplary embodiment of the present invention;

FIG. 8 illustrates a cross-sectional view of implanting p-type ions in one exemplary embodiment of the present invention; and

FIG. 9 illustrates a cross-sectional view of a semiconductor device with n-type and p-type thin film transistors in another exemplary embodiment of the present invention.

### DETAILED DESCRIPTION OF THE INVENTION

A semiconductor device with a lightly doped drain and a method of manufacturing the semiconductor device are provided to eliminate variations in the LDD length and simplify the manufacturing process. In one exemplary embodiment of the present invention, a method of forming a semiconductor device, such as driver/control circuits of LCD device, is illustrated. As shown in FIG. 1, the method includes steps of providing a semiconductor substrate 100, such as a silicon substrate, a silicon layer formed on an insulating layer, or a layer of any semiconductor material as appropriate. The semiconductor substrate 100 includes a first area 110 and a second area 120 for respectively forming a first type transistor and a second type transistor, such as an n-type thin film transistor and a p-type thin film transistor.

As shown in FIG. 1, the exemplary substrate 100 is a silicon layer 102 formed on an insulating layer 104, which includes an oxide layer formed on a quartz or glass substrate (106). The first area 110 is shown in the driver area 200 or the pixel area 300 of the semiconductor device. The second area 120 is shown in the driver area 200 of the semiconductor device.

Then, a gate dielectric layer 112 is formed on the substrate 100. The gate dielectric layer 112, which is selected form the group consisting of a nitride layer, an oxide layer, and a combination thereof, can be formed by the thermal oxidation technique or the deposition technique. A conductive layer 114 is subsequently formed on the gate dielectric layer 112. The conductive layer 114 can be a polysilicon layer or a layer of any conductive material and formed by the deposition technique. Then, a portion of the conductive layer 114 is selectively removed to form a first gate electrode 118 on the gate dielectric layer 112, which corresponds to the first area 110, and a portion of remains of the conductive layer 114 substantially overlies the second area 120, as shown in FIG. 3.

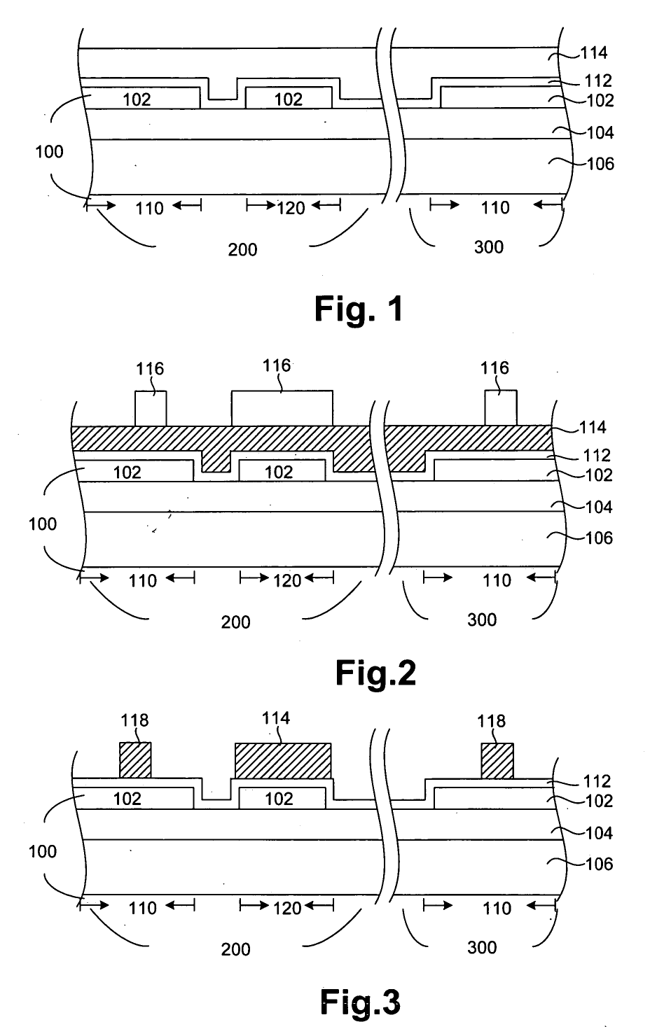

Referring to FIG. 2, the step of selectively removing the conductive layer 114 to form the first gate electrode 118 includes the step of forming a photoresist layer 116 on the conductive layer 114. The photoresist layer 116 is patterned to define the first gate electrode 118 of the conductive layer 114 corresponding to the first area 110. The formation of the patterned photoresist layer 116 can be achieved by a convention photolithography technique including coating, exposure, and development processes. As shown in FIG. 3, the conductive layer 114 is etched to expose the gate dielectric layer 112 by using the patterned photoresist layer 116 as a mask, so that a first portion of the conductive layer 114 forms the first gate electrode 118, and a second portion of the conductive layer 114 substantially overlies the second area 120. It is noted that the remains of the photoresist layer 116 is removed after the formation of the first gate electrode 118.

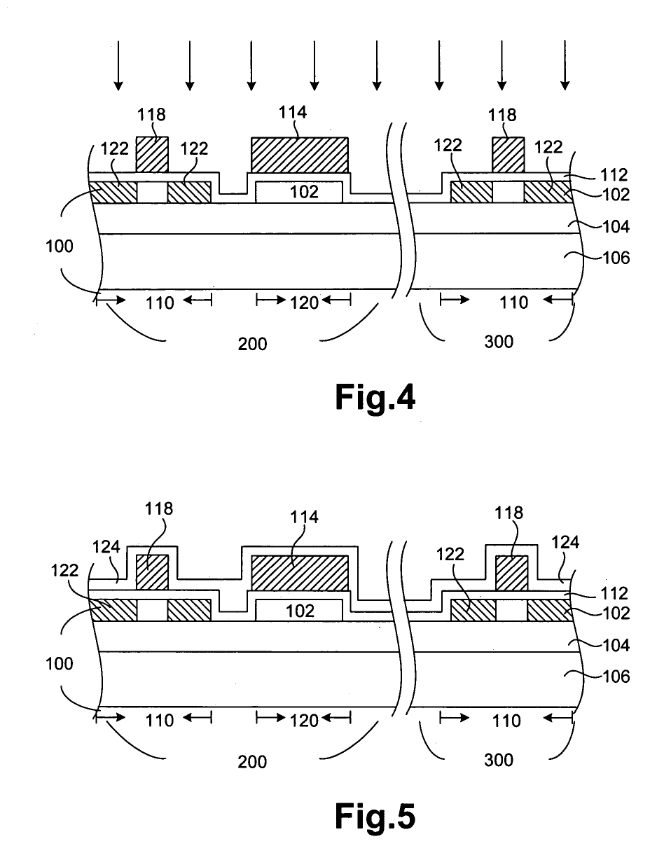

As shown in FIG. 4, a first impurity of a first conduction type is doped in the first area 110 by using the patterned transferred conductive layer as a mask. For example, the first n-type dopants are ion-implanted into the silicon layer 102 in the first area 110 to form at least one lightly doped region 122 by using the gate electrode 118 and the remains of the conductive layer 114 as a mask. The first n-type dopants can be selected from the group consisting of phosphorous, arsenic, and the like as appropriate.

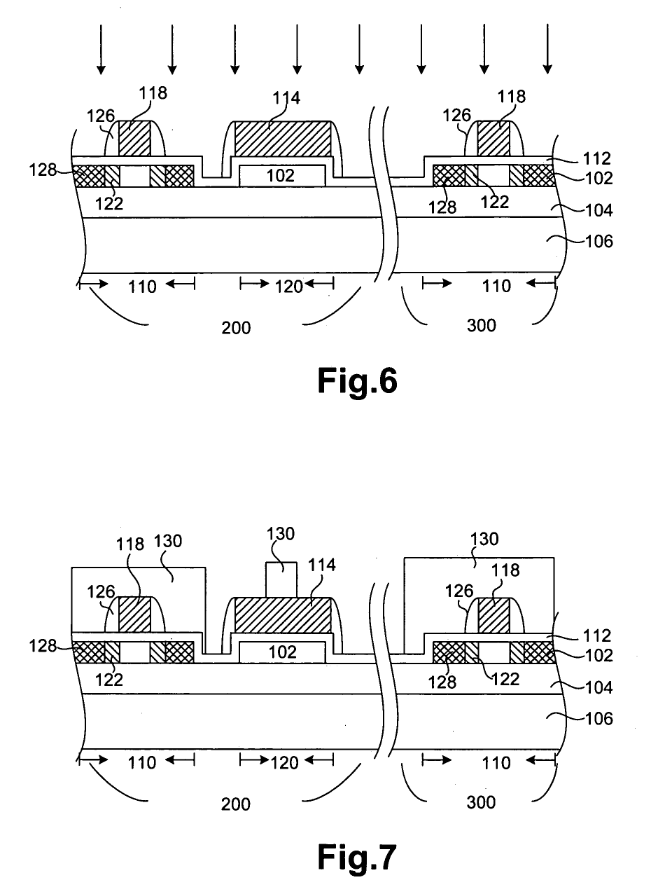

As shown in FIGS. 5 and 6, a conformal dielectric layer 124 is formed over the semiconductor substrate 100 and then anisotropically etched to form a spacer 126 on the sidewall of the first gate electrode 118. Then, a second impurity of the first conduction type is doped on the first area. For example, the second n-type dopants are ion-implanted into the silicon layer 102 in the first area 110 to form at least one heavy doped region 128 by using the first gate electrode 118 and the spacer 126 as a mask. The heavy doped region 128 adjacent to a portion of the lightly doped region 122. Therefore, the lightly doped drain 122 formed in the n-type transistor has the same length due to the symmetrical feature of the spacer 126 as shown in FIG. 6. The second n-type dopants can be selected from the group consisting of phosphorous, arsenic, and the like as appropriate. It is noted that the first and second impurities of the first conduction type can be two different doping materials or the same doping material. For example, the first and second n-type dopants can both be phosphorous, or respectively be phosphorous and arsenic.

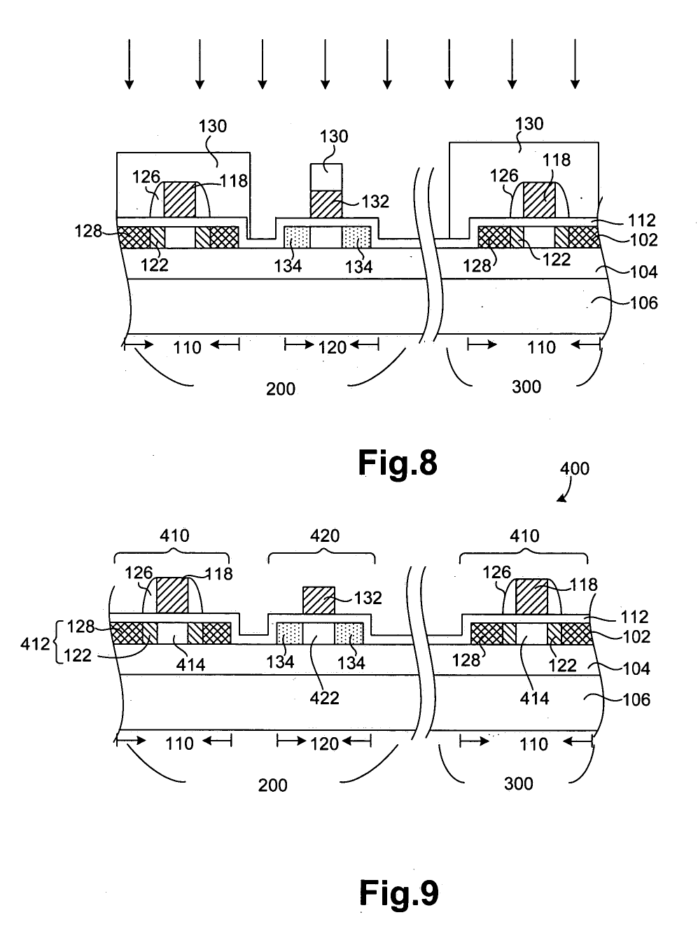

As shown in FIG. 7, a patterned mask layer 130, which defines a second gate electrode 132 of the conductive layer 114 corresponding to the second area 120, is formed over the semiconductor substrate 100. As shown in FIG. 8, a portion of the conductive layer 114, which corresponds to the second area 120, is etched to form the second electrode 132 on the dielectric layer 112 corresponding to the second area 120 by using the patterned mask layer 130 as a mask. As also shown in FIG. 8, an impurity of a second conduction type is doped in the second area 120 of the semiconductor substrate 110. For example, p-type dopants are ion-implanted in into the silicon layer 102, which corresponds to the second area 120, to form at least one doped region 134 by using the patterned mask layer 130 as a mask to form the p-type transistor. Then, the patterned mask layer 130 is removed as shown in FIG. 9.

The method further includes the steps of forming capacitors, contacts, wire circuits, and pixel contacts (not shown) to accomplish the formation of driver/pixel-control circuits of an LCD device. Furthermore, though the exemplary embodiment is illustrated to form driver/pixel-control circuits of LCD devices, it is noted that the method can be implemented to form other semiconductor devices with lightly doped drain.

A shown in FIG. 9, in another exemplary embodiment, a semiconductor device 400, with a lightly doped region 122 is also provided. The semiconductor device 400 includes a semiconductor substrate 100 having a first area 110 and a second area 120, a first type. thin film transistor 410 formed in the first area 110, and a second type thin film transistor 420 formed in the second area 120. As described above, the semiconductor substrate 100 can be a silicon substrate, or a substrate having a silicon layer 102 formed on an insulating layer 104 and a quartz or glass substrate 106. The first type thin film transistor 410 and the second type thin film transistor 420 can respectively be an n-type thin film transistor and a p-type thin film transistor shown in the driver area 200 or the pixel area 300.

The first type thin film transistor 410 includes first source/drain regions 412 formed in the semiconductor substrate 100 and separated by a first channel 414. The first gate dielectric layer 112, which is formed on the semiconductor substrate 100, covers the first channel 414. The first gate electrode 118, which is formed on the first gate dielectric layer 112, corresponds to the first channel 414. A spacer 126 is formed on a sidewall of the first gate electrode 118 and on the first gate dielectric layer 112. A lightly doped region 122, which is formed in a portion of the source/drain region 412, corresponds to the spacer 126. In other words, the first source/drain region 412 includes a heavy doped region 128 and a lightly doped region 122.

The second type thin film transistor 420 includes second source/drain regions 134 formed in the semiconductor substrate 100 and separated by a second channel 422. The second gate dielectric layer 112 is formed on the semiconductor substrate 100 to cover the second channel 422. The second gate electrode 132, which is formed on the second gate dielectric layer 112, corresponds to the second channel 422. As shown in FIG. 9, the first gate dielectric layer and the second gate dielectric layer formed at the same time is the gate dielectric layer 112. The second-source/drain regions are the doped regions 134.

Although specific embodiments have been illustrated and described, it will be obvious to those skilled in the art that various modifications may be made without departing from what is intended to be limited solely by the appended claims.

What is claimed is

1. A method of manufacturing a semiconductor device, said semiconductor device comprising a first conduction type thin film transistor and a second conduction type thin film transistor, said method comprising:
providing a substrate having a first area and a second area;
forming a gate dielectric layer on said substrate;
forming a conductive layer on said gate dielectric layer;
selectively removing a portion of said conductive layer to form a first gate electrode on said gate dielectric layer corresponding to said first area and a portion of remains of said conductive layer substantially overlying said second area;
doping a first impurity of a first conduction type in said first area;
forming a spacer on a sidewall of said first gate electrode;
doping a second impurity of said first conduction type in said first area to form said first conduction type thin film transistor;
removing a portion of said conductive layer corresponding to said second area to form a second gate electrode on said gate dielectric layer corresponding to said second area; and
doping an impurity of a second conduction type in said second area to form said second conduction type thin film transistor.

2. The method of claim 1, wherein said step of selectively removing said conductive layer to form said first gate electrode comprises:
forming a photoresist layer on said conductive layer;
patterning said photoresist layer so that said photoresist layer defines said first gate electrode of said conductive layer corresponding to said first area; and
etching said conductive layer to expose said gate dielectric layer using said photoresist layer as a mask, so that a first portion of said conductive layer forms said first gate electrode, and a second portion of said conductive layer substantially overlies said second area.

3. The method of claim 1, wherein said step of doping said first impurity of said first conduction type comprises a step of ion implanting a fist n-type dopant into said first area to form at least one lightly doped region by using said first gate electrode as a mask.

4. The method of claim 3, wherein said step of doping said second impurity of said first conduction type comprises a step of ion implanting a second n-type dopant into said first area to form at least one heavy doped region by using said first gate electrode and said spacer as a mask, and wherein said heavy doped region overlaps a portion of said lightly doped region.

5. The method of claim 1, wherein said first and said second impurities of said first conduction type are two different or same doping materials.

6. The method of claim 5, wherein said impurity of said second conduction type comprises a p-type dopant.

7. The method of claim 5, wherein said step of doping said impurity of said second conduction type comprises a step of ion implanting a p-type dopant into said second area to form at least one doped region by using said patterned photoresist layer as a mask.

8. The method of claim 1, wherein said step of forming said spacer comprises:
forming a conformal dielectric layer over said semiconductor substrate; and
anisotropically etching said conformal dielectric layer to form said spacer on said sidewall of said first gate electrode.

9. The method of claim 1, wherein said gate dielectric layer is selected from the group consisting of a nitride layer, an oxide layer, and a combination thereof.

10. A method of manufacturing a semiconductor device, said semiconductor device comprising an n-type thin film transistor and a p-type thin film transistor, said method comprising:
providing a substrate having a first area and a second area;
forming a gate dielectric layer on said substrate;
forming a conductive layer on said gate dielectric layer;
selectively removing a portion of said conductive layer, so that a first portion of said conductive layer forms a first gate electrode on said gate dielectric layer corresponding to said first area, and a second portion of said conductive layer substantially over said second area;
ion implanting a first n-type dopant into said first area to form a lightly doped region by using said first gate electrode as a mask;
forming a conformal dielectric layer over said semiconductor substrate;
etching said conformal dielectric layer to form a spacer on a sidewall of said first gate electrode;
ion implanting a n-type dopant into said first area to form a heavy doped region by using said spacer and said first gate electrode as a mask, said heavy doped region overlapping a portion of said lightly doped region to form said n-type thin film transistor with said lightly doped region;
removing a portion of said second portion of said conductive layer to form a second gate electrode on said gate dielectric layer corresponding to said second area; and
ion implanting a p-type dopant into said second area by using said patterned photoresist layer as a mask to form said p-type transistor.

11. The method of claim 10, wherein said first n-type dopant and said second n-type dopant are two different doping materials.

12. The method of claim 10, wherein said first n-type dopant and said second n-type dopant are the same doping materials.

13. The method of claim 10, wherein said gate dielectric layer is selected from the group consisting of a nitride layer, an oxide layer, and a combination thereof.

14. A semiconductor device with a lightly doped region, comprising:
a substrate having a first area and a second area;
a first type thin film transistor formed in said first area; and
a second type thin film transistor formed in said second area;
wherein said first type thin film transistor comprises:
first source/drain regions formed in said substrate and separated by a first channel;
a first gate dielectric layer formed on said substrate covering said first channel;
a first gate electrode formed on said first gate dielectric layer corresponding to said first channel;
a spacer formed on a sidewall of said first gate electrode; and a lightly doped region formed in a portion of said source/drain region corresponding to said spacer;
and wherein said second type thin film transistor comprises:
second source/drain regions formed in said substrate and separated by a second channel;
a second gate dielectric layer formed on said substrate covering said second channel; and
a second gate electrode formed on said second gate dielectric layer corresponding to said second channel.

15. The semiconductor device of claim 14, wherein said first and second type thin film transistors comprises an n-type and a p-type thin film transistors.

16. The semiconductor device of claim 14, wherein said first and second dielectric layers are selected from the group consisting of a nitride layer, an oxide layer, and a combination thereof.
